(19) United States
(12) Patent Application Publication
(10) Pub. No.: US 2025/0246522 A1
(43) Pub. Date: Jul. 31, 2025

(54) SEMICONDUCTOR MODULE

(71) Applicant: FUJI ELECTRIC CO., LTD., Kawasaki-shi (JP)

(72) Inventors: Kouta INADA, Kawasaki-shi (JP); Shun HARASHIMA, Kawasaki-shi (JP)

(73) Assignee: FUJI ELECTRIC CO., LTD., Kawasaki-shi (JP)

(21) Appl. No.: 18/962,351

(22) Filed: Nov. 27, 2024

(30) Foreign Application Priority Data
Jan. 25, 2024 (JP) 2024-009377

(51) Int. Cl. H01L 23/495; H01L 23/00; H01L 23/31; H01L 23/473; H01L 25/16

(52) U.S. Cl. CPC H01L 23/49555; H01L 23/3135; H01L 23/49513; H01L 23/4952; H01L 23/473; H01L 24/32; H01L 24/48; H01L 25/16; H01L 2224/32245; H01L 2224/48137; H01L 2924/13055; H01L 2924/13091

(57) ABSTRACT

A semiconductor module includes: a semiconductor element, a sealing member having a main body portion sealing the semiconductor element, and a plurality of leads, each of the leads having an inner lead portion extending to an inside of the main body portion of the sealing member and an outer lead portion extending to an outside of the main body portion, the outer lead portion being bent at a predetermined bending position, in which the sealing member has a covering portion individually covering, for each section of the outer lead portion, an entire surface of the section of the outer lead portion of the lead, in which the section is defined from a boundary between the inner lead portion and the outer lead portion to a position closer to the boundary than the bending position.

### CROSS-REFERENCE TO RELATED APPLICATION

This application is based upon and claims the benefit of priority to Japanese Patent Application No. 2024-009377, filed on Jan. 25, 2024, the entire contents of which are incorporated herein by reference.

### BACKGROUND OF THE INVENTION

### 1. Technical Field

The present invention relates to a semiconductor module.

### 2. Description of the Related Art

In a dual inline package (DIP) type semiconductor module, an outer lead portion of a lead is coated with a coating material different from a sealing member for sealing a semiconductor element in order to increase a creepage distance associated with insulation performance (refer to, for example, JP 2020-53611 A). In addition, in order to increase the creepage distance between the leads, the sealing member has a protrusion formed to protrude between the leads (refer to, for example, JP 2013-84838 A and JP H06-61375 A).

### SUMMARY OF THE INVENTION

When the creepage distance is increased by the above-described method, manufacturing costs increase due to an increase in the number of manufacturing steps, an increase in the amount of used material, and the like.

In one aspect, an object of the present invention is to suppress an increase in manufacturing costs of a semiconductor module due to an increase in creepage distance related to insulation performance.

A semiconductor module according to one aspect includes: a semiconductor element; a sealing member having a main body portion sealing the semiconductor element; and a plurality of leads, each of the leads having an inner lead portion extending to an inside of the main body portion of the sealing member and an outer lead portion extending to an outside of the main body portion, the outer lead portion being bent at a predetermined bending position, in which the sealing member has a covering portion individually covering, for each section of the outer lead portion, an entire surface of the section of the outer lead portion of the lead, in which the section is defined from a boundary between the inner lead portion and the outer lead portion to a position closer to the boundary than the bending position.

According to the above-described aspect, it is possible to suppress an increase in manufacturing costs of a semiconductor module due to an increase in creepage distance related to insulation performance.

### BRIEF DESCRIPTION OF THE DRAWINGS

FIG. 1 is a bottom view of a semiconductor module according to an embodiment;

FIG. 2 is a cross-sectional view illustrating a first configuration example in a sealing member in the semiconductor module illustrated in FIG. 1;

FIG. 3 is a cross-sectional view illustrating a second configuration example in the sealing member in the semiconductor module illustrated in FIG. 1;

FIG. 4 is a circuit diagram illustrating a circuit configuration example of the semiconductor module illustrated in FIG. 1;

FIG. 5 is an enlarged perspective view of the periphery of a covering portion in the semiconductor module illustrated in FIG. 1;

FIG. 6 is a view (part 1) illustrating a method of manufacturing the semiconductor module according to the embodiment;

FIG. 7 is a view (part 2) illustrating the method of manufacturing the semiconductor module according to the embodiment;

FIG. 8 is a view illustrating a relationship between a lead frame and a cavity of a mold;

FIG. 9 is a cross-sectional view taken along an alternate long and short dash line B-B′in FIG. 8;

FIG. 10 is a bottom view illustrating an example of a step of dividing a lead into the individual leads;

FIG. 11 is a front view illustrating an example of a step of bending an outer lead portion;

FIG. 12 is a bottom view illustrating a modification of the shape of the covering portion; and

FIG. 13 is a cross-sectional view taken along an alternate long and short dash line C-C′ in FIG. 12.

### DETAILED DESCRIPTION

Hereinafter, an embodiment of the present invention will be described in detail with reference to the drawings. A “semiconductor module” in the following description is obtained by sealing a semiconductor element (a semiconductor chip) with an insulating material, and may be referred to as a “semiconductor device”, a “semiconductor package”, or the like.

An X axis, a Y axis, and a Z axis in each of the drawings to be referred to are illustrated for the purpose of defining a plane and a direction in the illustrated semiconductor module. The X axis, the Y axis, and the Z axis are perpendicular to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction of an arrow (positive or negative) of the X axis, the Y axis, and the Z axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Further, when the term “upper surface of the member A” is described, the surface includes a surface that is positioned at the end of the member A on the positive side in the Z direction and faces the positive side in the Z direction. These directions and surfaces associated with the directions are words used for convenience of description, and a correspondence relationship with the directions of the X axis, the Y axis, and the Z axis may change depending on a mounting posture of the semiconductor module and the like. For example, in the present specification, a surface facing a die pad in the semiconductor element is referred to as a lower surface, and a surface opposite the lower surface is referred to as an upper surface, but the present invention is not limited thereto, and the surface facing the die pad may be referred to as the upper surface, and the surface opposite the upper surface may be referred to as the lower surface.

An aspect ratio and a size relationship between respective members in each drawing are merely schematically represented, and do not necessarily coincide with a relationship in a semiconductor module actually manufactured. For convenience of description, it is also assumed that the size relationship between the respective members is exaggerated. In addition, some of the cross-sectional views illustrate a cross-sectional configuration of the semiconductor module cut along a virtual cutting line that cannot be accurately illustrated in the plan view for convenience of description.

The descriptions of “not illustrated” and the like in the present specification are intended not to clearly indicate which part in the drawing a component to which the description is given is using a specific reference sign and a leader line. For example, a “first main electrode not illustrated” means that a portion representing the first main electrode (for example, a figure, a line, or the like) is not illustrated in the drawing, and that there is neither a reference sign nor a leader line clearly indicating a portion corresponding to the first main electrode in the figure. In addition, the underlined reference signs in the drawings indicate the entire components including a plurality of portions distinguished from one another by a plurality of reference signs.

A semiconductor module to be exemplified in the following description may be applied to, for example, a power conversion device such as an industrial or electrical (for example, an in-vehicle motor's) inverter device. Thus, in the following description, detailed description of the same or similar configuration, function, operation, manufacturing method, and the like as or to those of a known semiconductor module will be omitted.

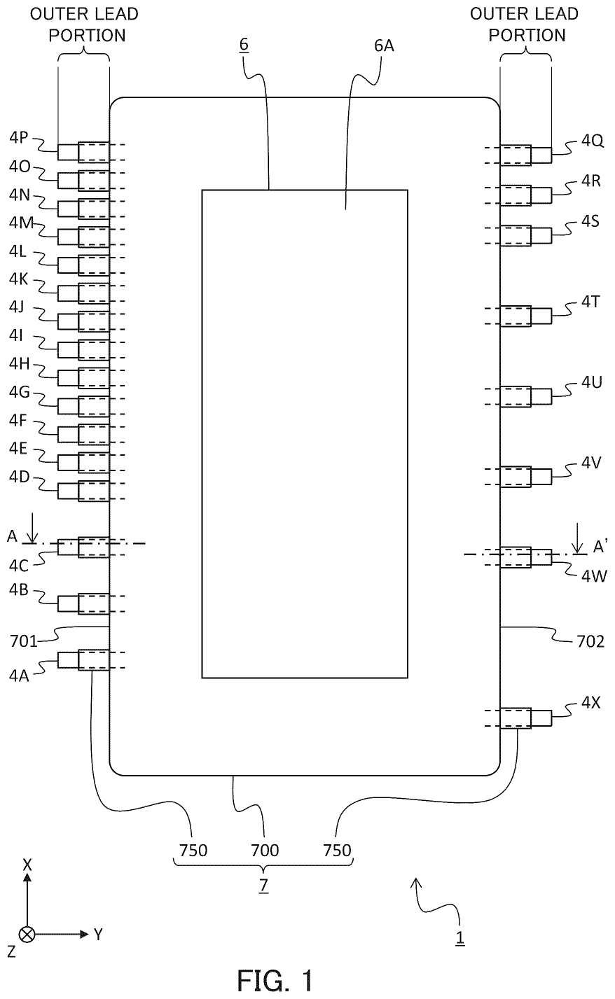

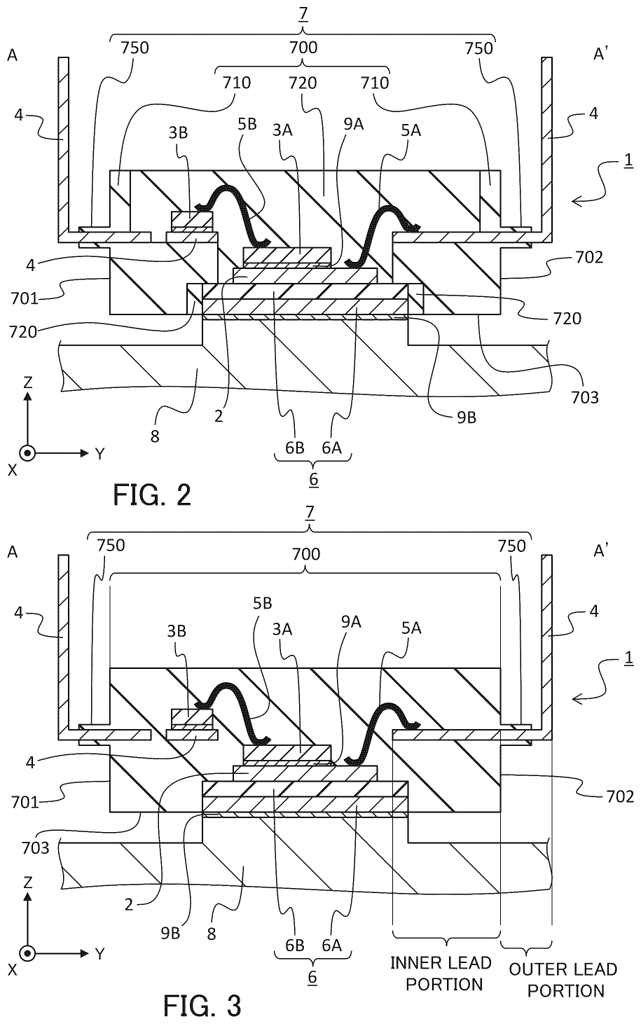

FIG. 1 is a bottom view of a semiconductor module according to an embodiment. FIG. 2 is a cross-sectional view illustrating a first configuration example in a sealing member in the semiconductor module illustrated in FIG. 1. FIG. 3 is a cross-sectional view illustrating a second configuration example in the sealing member in the semiconductor module illustrated in FIG. 1. The cross-sectional views of FIGS. 2 and 3 illustrate a cross-sectional configuration example of a semiconductor module 1 cut by a virtual cutting line obtained by connecting an alternate long and short dash line A passing through one lead located on the negative side in the Y direction to another alternate long and short dash line A′ passing through another lead located on the positive side in the Y direction in the semiconductor module 1 illustrated in FIG. 1.

The semiconductor module 1 illustrated in FIGS. 1 to 3 includes a die pad 2, semiconductor elements 3A and 3B, a lead 4 (4A to 4X), a bonding wire 5 (5A and 5B), a heat dissipation member 6, and a sealing member 7. Although the semiconductor module 1 may include a cooler 8 (refer to FIG. 2) positioned below the heat dissipation member 6, a dual inline package (DIP) semiconductor package excluding the cooler 8 illustrated in FIGS. 2 and 3 is referred to as the semiconductor module 1 in the present specification. In addition, in the present specification, when a specific lead among the plurality of leads 4A to 4X is designated, a reference sign (any one of 4A to 4X) allocated to the specific lead is described in FIG. 1, and in other cases, the lead is simply described as the “lead 4”. Similarly, when a specific bonding wire of the plurality of bonding wires 5A and 5B is designated, a reference sign (any one of 5A and 5B) allocated to the specific bonding wire is described in FIG. 2 and the like, and in other cases, the bonding wire is simply described as the “bonding wire 5”.

The die pad 2 is a component configured to allow the semiconductor element 3A to be mounted thereon, in which the semiconductor element 3A may be referred to as a semiconductor chip or a die. The semiconductor element 3A may be, for example, a reverse conducting (RC)-IGBT element obtained by integrating an insulated gate bipolar transistor (IGBT) element, which is a switching element, with a function of a diode element such as a free wheeling diode (FWD) clement connected in antiparallel to the IGBT element. In addition, the semiconductor element 3A can be, for example, a metal oxide semiconductor field effect transistor (MOSFET) element which is a switching element. This type of semiconductor elements 3A has a first main electrode (not illustrated) provided on the lower surface thereof, and has a second main electrode and a control electrode (a gate electrode) (not illustrated) provided on the upper surface thereof. When the switching element of the semiconductor element 3A is the IGBT element, the first main electrode on the lower surface side may be referred to as a collector electrode, and the second main electrode on the upper surface side may be referred to as an emitter electrode. A semiconductor substrate forming the switching element and the diode element in the semiconductor element 3A is not limited to a silicon substrate, and may be, for example, a substrate using a wide band gap semiconductor such as a silicon carbide (SiC) substrate or a gallium nitride (GaN) substrate.

For example, the semiconductor element 3A is bonded to the upper surface of the die pad 2 with a bonding material 9A such as solder interposed therebetween, and the first main electrode is electrically connected to the die pad 2. The die pad 2 is electrically connected to the lead 4 (any one of 4Q to 4X) extending from the sealing member 7 to the positive side in the Y direction by the bonding wire 5A. In addition, the second main electrode of the semiconductor element 3A is electrically connected to another lead 4 (any one of the leads not connected to the bonding wire 5A among 4Q to 4X) extending from the sealing member 7 to the positive side in the Y direction by a bonding wire (not illustrated). The control electrode of the semiconductor element 3A is electrically connected to the semiconductor clement 3B, which is a control IC, using the bonding wire 5B. The semiconductor clement 3B is bonded to an upper surface of a portion (an inner lead portion) of the lead 4 with a bonding material interposed therebetween, in which the portion is embedded in the sealing member 7. The number and type of semiconductor elements bonded to the upper surface of the die pad 2 and the upper surface of the inner lead portion are not limited to a specific number and type. For example, a semiconductor element functioning as the above-described IGBT element and a semiconductor element functioning as the above-described diode element may be bonded to the upper surface of the die pad 2 so as to be connected in antiparallel.

The heat dissipation member 6 is connected to the lower surface of the die pad 2. The heat dissipation member 6 includes a metal layer 6A exposed from a lower surface 703 of the sealing member 7 and an insulating layer 6B disposed on the upper surface of the metal layer 6A. The metal layer 6A is formed of, for example, a metal plate or a metal foil such as copper or aluminum. The insulating layer 6B may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating layer 6B may be, for example, a substrate obtained by molding an insulating resin such as epoxy resin, a substrate obtained by impregnating a base material such as a glass fiber with an insulating resin, a substrate obtained by coating the surface of a flat plate-shaped metal core with an insulating resin, or the like. The heat dissipation member 6 may be a direct copper bonding (DCB) substrate or an active metal brazing (AMB) substrate in which a metal layer is also formed on the upper surface of the insulating layer 6B. The metal layer formed on the upper surface of the insulating layer 6B may be the die pad 2, or may be a metal plate or a metal foil different from the die pad 2. A set of the die pad 2 and the heat dissipation member 6 is an example of an element mounting member configured to allow a semiconductor element to be mounted thereon.

Among the die pad 2, the semiconductor elements 3A and 3B, the bonding wire 5, and the lead 4, a connection portion with the bonding wire 5 and a peripheral portion thereof (hereinafter referred to as an “inner lead portion”) are sealed by the sealing member 7. The sealing member 7 in the semiconductor module 1 according to the present embodiment has a main body portion 700 and a covering portion 750. The main body portion 700 is a substantially rectangular portion in which the die pad 2, the semiconductor elements 3A and 3B, the bonding wire 5, and the inner lead portion of the lead 4 are sealed such that the lower surface (the metal layer 6A) of the heat dissipation member 6 is exposed. The covering portion 750 is a substantially tubular portion that covers a portion of the lead 4 for each outer lead portion, in which the portion extends outwards from the main body portion 700 (hereinafter referred to as an “outer lead portion”).

As described above, the semiconductor module 1 of the present embodiment is the DIP type semiconductor package, and the lead 4 extends outwards from an end surface 701 and an end surface 702 located at the end of the main body portion 700 of the sealing member 7 in the direction (Y direction) parallel to the in-plane direction of the lower surface 703. The leads 4A to 4P (each used for a control signal) extend to the negative side in the Y direction from the end surface 701 located on the negative side in the Y direction of the main body portion 700, and the leads 4Q to 4X (for each used for a main current) extend to the positive side in the Y direction from the end surface 702 located on the positive side in the Y direction of the main body portion 700. For example, as illustrated in FIGS. 2 and 3, the lead 4 of the semiconductor module 1 is bent at a bending position of an outer lead portion. A section of the outer lead portion from the bending position of the outer lead portion to an end portion opposite a boundary between the inner lead portion and the outer lead portion is bent in a direction from the bending position toward the upper surface of the main body portion 700 (positive side in the Z direction). In other words, the outer lead portion of the lead 4 is bent in a direction away from the cooler 8 when the cooler 8 is connected to the lower surface of the semiconductor module 1. The cooler 8 is thermally connected to the metal layer 6A of the heat dissipation member 6 exposed from the lower surface 703 of the sealing member 7 with a heat conductive member 9B interposed therebetween, such as a thermal grease or a thermal compound. The cooler 8 may be a device configured to circulate a coolant such as cooling water so as to dissipate heat generated by the semiconductor element 3A. For example, the cooler 8 may dissipate, into the air, the heat generated by the semiconductor clement 3A such as a heat sink.

For example, as illustrated in FIG. 2, the main body portion 700 of the sealing member 7 includes a case member 710 having a space provided for accommodation of the semiconductor elements 3A, 3B, and the like, and an insulating filling member 720 filling the space of the case member 710. In this case, the lead 4 is integrated with the case member 710 such that a part of the inner lead portion is exposed in the space for accommodation of the semiconductor elements 3A, 3B, and the like of the case member 710, and is supported by the case member 710. In the semiconductor module 1 having the case member 710 formed therein, a set of the die pad 2 and the heat dissipation member 6 each serving as the element mounting member is boned to the case member 710 by the filling member 720 such that a surface (the lower surface of the heat dissipation member 6) opposite a surface (the upper surface of the die pad 2) having the semiconductor element 3A mounted thereon is exposed from the main body portion 700. In the semiconductor module 1 illustrated in FIG. 2, the covering portion 750 is individually and integrally formed with each of the leads 4 respectively disposed on the end surface 701 located on the negative side in the Y direction of the case member 710 and the end surface 702 located on the positive side in the Y direction of the case member 710.

It is noted that, in the main body portion 700 of the sealing member 7, for example, as illustrated in FIG. 3, the entire main body portion 700 may be formed of the same insulating resin, and the covering portion 750 may be individually and integrally formed with each of the leads 4 respectively disposed on the end surface 701 located on the negative side in the Y direction of the main body portion 700 and the end surface 702 located on the positive side in the Y direction of the main body portion 700.

The semiconductor module 1 described above with reference to FIGS. 1 to 3 may be a module including a three-phase inverter circuit and a control circuit, which may be referred to as an intelligent power module (IPM).

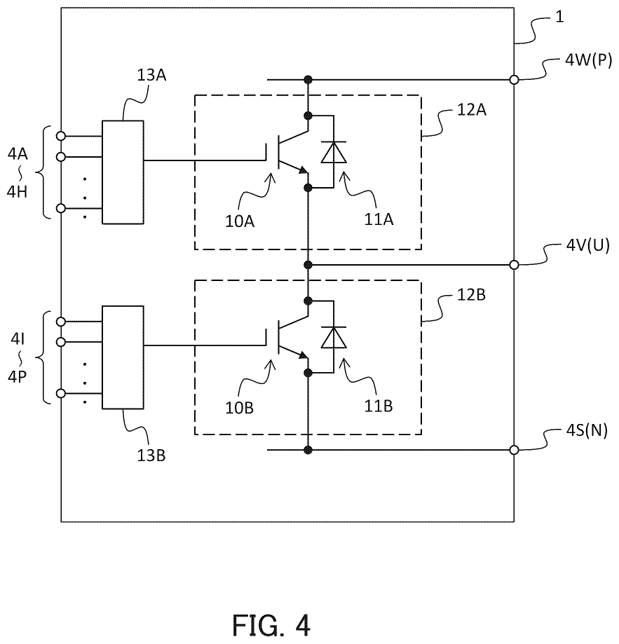

FIG. 4 is a circuit diagram illustrating a circuit configuration example of the semiconductor module illustrated in FIG. 1. FIG. 4 illustrates only a part of the three-phase inverter circuit and the control circuit included in the semiconductor module 1.

The semiconductor module 1 has a power conversion circuit formed therein and configured to convert a direct current into a three-phase alternating current of a U-phase, a V-phase, and a W-phase and to output the three-phase alternating current. FIG. 4 illustrates a half-bridge inverter circuit that outputs a direct current as a U-phase alternating current. The illustrated half-bridge inverter circuit includes two IGBT elements 10A and 10B connected in series between the first lead 4W and the second lead 4S, and diode elements (FWD elements) 11A and 11B respectively connected in antiparallel to the two IGBT elements 10A and 10B. The first lead 4W is a P terminal connected to the positive electrode of the DC power supply, and the second lead 4S is an N (U) terminal connected to the negative electrode of the DC power supply. A collector electrode of the IGBT element 10A of an upper arm 12A of the two IGBT elements is connected to the first lead 4W, and an emitter electrode of the IGBT element 10B of a lower arm 12B is connected to the second lead 4S. An emitter electrode of the IGBT element 10A of the upper arm 12A and a collector electrode of the IGBT element 10B of the lower arm 12B are connected to a third lead 4V which is an output terminal of a U-phase alternating current. A gate of the IGBT element 10A of the upper arm 12A is connected to a first control circuit 13A, and a gate of the IGBT element 10B of the lower arm 12B is connected to a second control circuit 13B. The leads 4A to 4H each extending from the end surface 701 of the main body portion 700 of the sealing member 7 to the negative side in the Y direction are connected to the first control circuit 13A, and the leads 4I to 4P each extending from the end surface 701 to the negative side in the Y direction are connected to the second control circuit 13B.

Each of the half-bridge inverter circuit that outputs the direct current as a V-phase alternating current and the half-bridge inverter circuit that outputs the direct current as a W-phase alternating current may have a circuit configuration similar to that of the half-bridge inverter circuit that outputs the direct current as the U-phase alternating current illustrated in FIG. 4. The first control circuit 13A controls a voltage to be applied to the gate of the IGBT element 10A of the U-phase, the V-phase, and the W-phase upper arms 12A based on drive power supply voltages and the like input from the plurality of leads 4A to 4H. The second control circuit 13B controls a voltage applied to the gate of the IGBT element 10B of the U-phase, the V-phase, and the W-phase lower arm 12B based on drive power supply voltage and the like input from the plurality of leads 41 to 4P.

The circuit configuration of the semiconductor module 1 described above with reference to FIG. 4 is merely an example of a power conversion circuit formed in the main body portion 700 of the sealing member 7. The circuit formed in the main body portion 700 may be a power conversion circuit having another circuit configuration. The circuit formed in the main body portion 700 may include a circuit different from the power conversion circuit, may have a part of the power conversion circuit formed therein, or may have only a circuit different from the power conversion circuit formed therein.

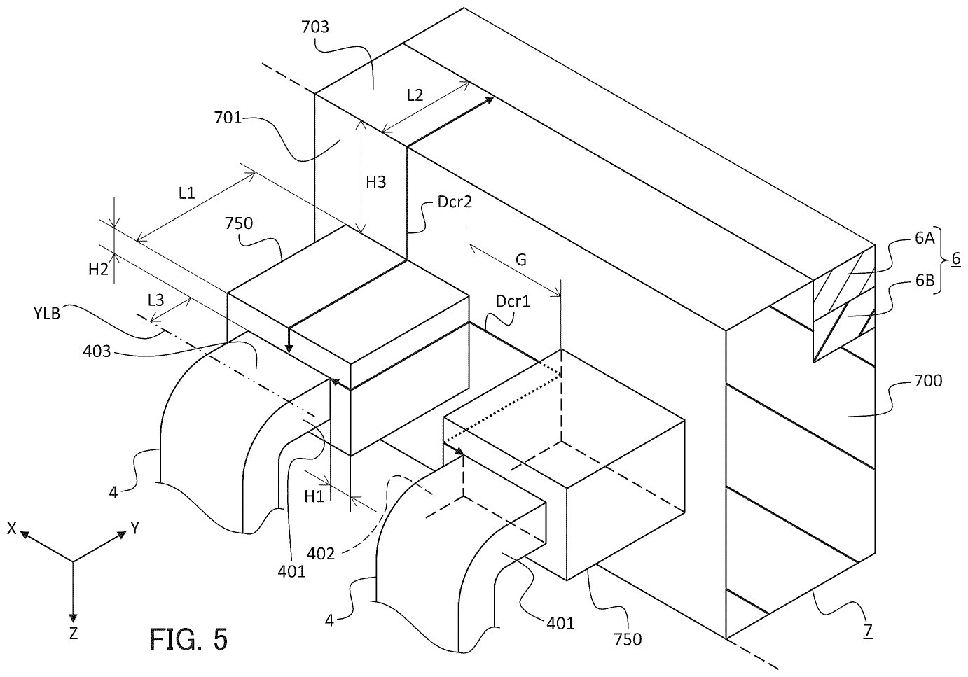

FIG. 5 is an enlarged perspective view of the periphery of a covering portion in the semiconductor module illustrated in FIG. 1. In the following description with reference to FIG. 5, only a configuration on the end surface 701 side of the main body portion 700 of the sealing member 7 will be described, and a configuration on the opposite end surface 702 side may be similar thereto.

In the semiconductor module 1 of the present embodiment, as described above, the outer lead portion of the lead 4 extending from the main body portion 700 of the sealing member 7 is covered with the covering portion 750 for each of the leads 4. For example, as illustrated in FIG. 5, the outer lead portion of the lead 4 is bent at a bending position YLB located away from the end surface 701 (in other words, a boundary between the inner lead portion and the outer lead portion) of the main body portion 700 of the sealing member 7 by a predetermined distance in the extending direction (Y direction) of the lead 4. The covering portion 750 is formed to be integrated with the main body portion 700, and covers the entire surface of a section of the outer lead portion, in which the section has a length L1 from the end surface 701 of the main body portion 700 to a predetermined position closer to the end surface 701 side of the main body portion 700 than the bending position YLB.

Respective thicknesses H1 from side surfaces 401 and 402 of the outer lead portions of the covering portions 750 illustrated in FIG. 5 are the same thickness. The side surfaces 401 and 402 are surfaces facing the surfaces of the adjacent outer lead portions each extending from the end surface 701 of the main body portion 700 among the surfaces of the outer lead portions. Therefore, when a gap between the adjacent covering portions 750 is defined as G and a length of the covering portion 750 in the extending direction (Y direction) of the lead 4 is defined as L1, a creepage distance Dcr1 between the adjacent leads 4 (outer lead portions) extending from the end surface 701 of the main body portion 700 is the sum of the gap G between the adjacent covering portions 750, the respective thicknesses HI from the side surfaces 401 and 402 of the outer lead portion of the covering portion 750, and the respective lengths LI of the covering portions 750 respectively covering the adjacent leads 4. That is, the creepage distance Dcr1 between the adjacent leads 4 (outer lead portions) extending from the end surface 701 of the main body portion 700 is the sum of the length from the side surface 401 of the lead 4 (outer lead portion) to the side surface 402 of the adjacent lead 4 (outer lead portion) and the respective lengths L1 of the covering portions 750 respectively covering the adjacent leads 4. It is noted that the respective thicknesses H1 from the side surfaces 401 and 402 of the outer lead portions of the illustrated covering portions 750 are not limited to the same thickness, and the thicknesses may be different from each other. Additionally, regarding the length L1 of the covering portion 750, the lengths of the covering portions 750 respectively covering the adjacent leads 4 may be different from each other as long as the creepage distance can be secured.

Further, the covering portion 750 may have a thickness H2 of 1 mm or less at a lower surface 403 and the upper surface (not illustrated) of the outer lead portion. On the other hand, the thickness of the main body portion 700 in the vertical direction (Z direction) may be several mm to several tens of mm. When a distance from the end surface 701 of the main body portion 700 on the lower surface 703 of the main body portion 700 to the metal layer 6A of the heat dissipation member 6 is defined as L2, and a distance from the lower surface 703 of the main body portion 700 to the covering portion 750 is defined as H3, a creepage distance Dcr2 between the lead 4 (outer lead portion) and the metal layer 6A of the heat dissipation member 6 is the sum of the distance L2 from the end surface 701 to the metal layer 6A of the heat dissipation member 6, the distance H3 from the lower surface 703 to the covering portion 750, the length L1 in the extending direction (Y direction) of the lead 4 in the covering portion 750, and the respective thicknesses H1 from the side surfaces 401 and 402 of the outer lead portions.

That is, in the semiconductor module 1 of the present embodiment, since the scaling member 7 has the covering portion 750 covering the outer lead portion of the lead 4, the creepage distance between the adjacent leads 4 (outer lead portions) can be increased by the total distance of the respective lengths L1 of the covering portions 750 respectively covering the adjacent leads 4 as compared with a semiconductor module not having the covering portion 750. In addition, in the semiconductor module 1 of the present embodiment, the creepage distance between the lead 4 (outer lead portion) and the metal layer 6A of the heat dissipation member 6 can be increased by the length L1 of the covering portion 750 as compared with the semiconductor module not having the covering portion 750. It is noted that the covering portion 750 does not need to be provided on all of the leads 4A to 4X, and may be provided only on the lead 4 required to secure the creepage distance. For example, the covering portions 750 may be provided on the respective leads 4Q to 4X each used for the main current.

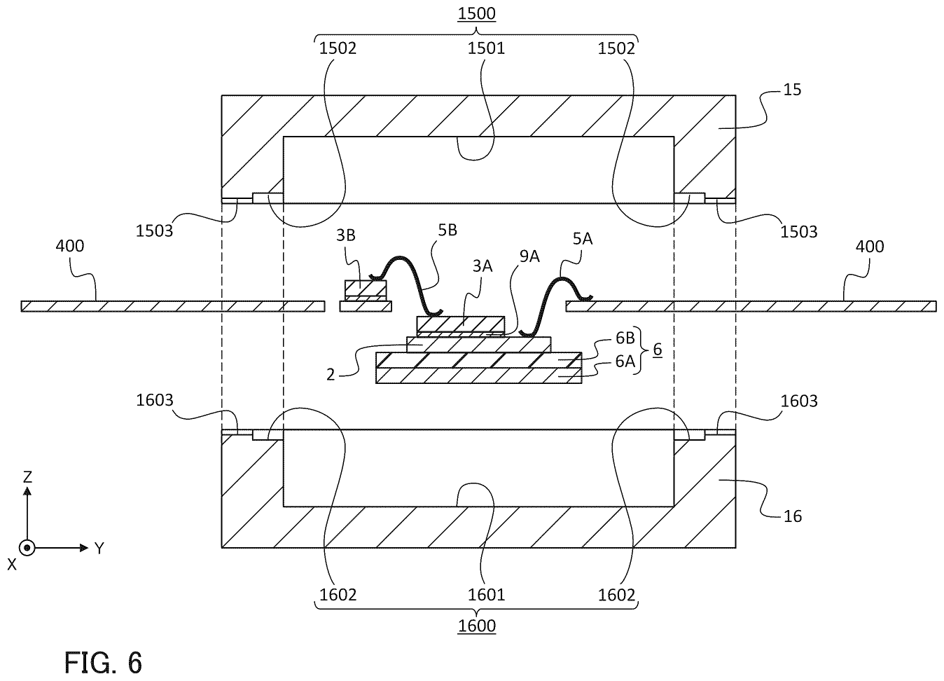

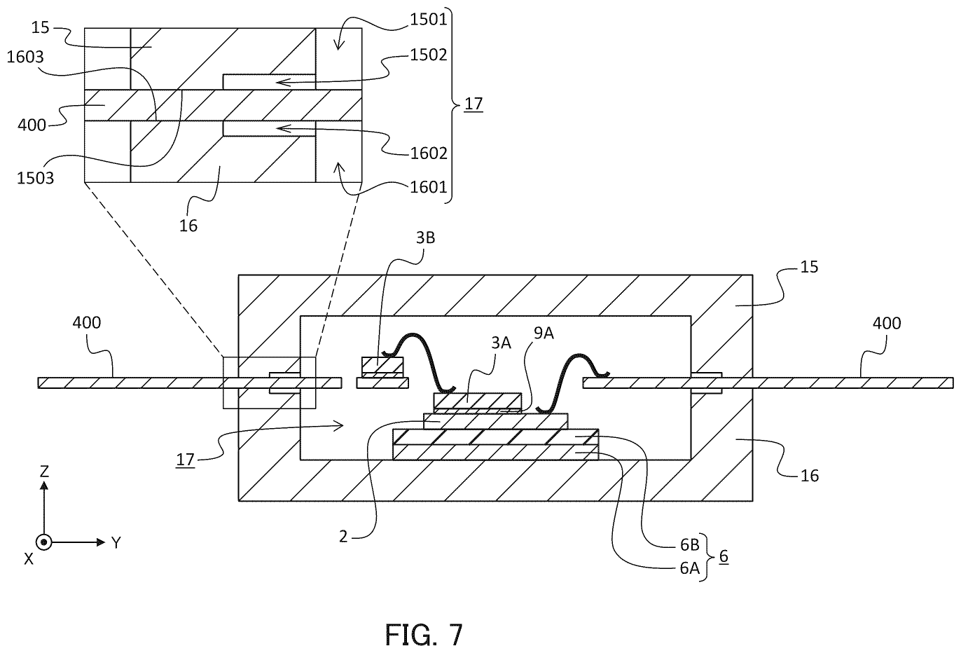

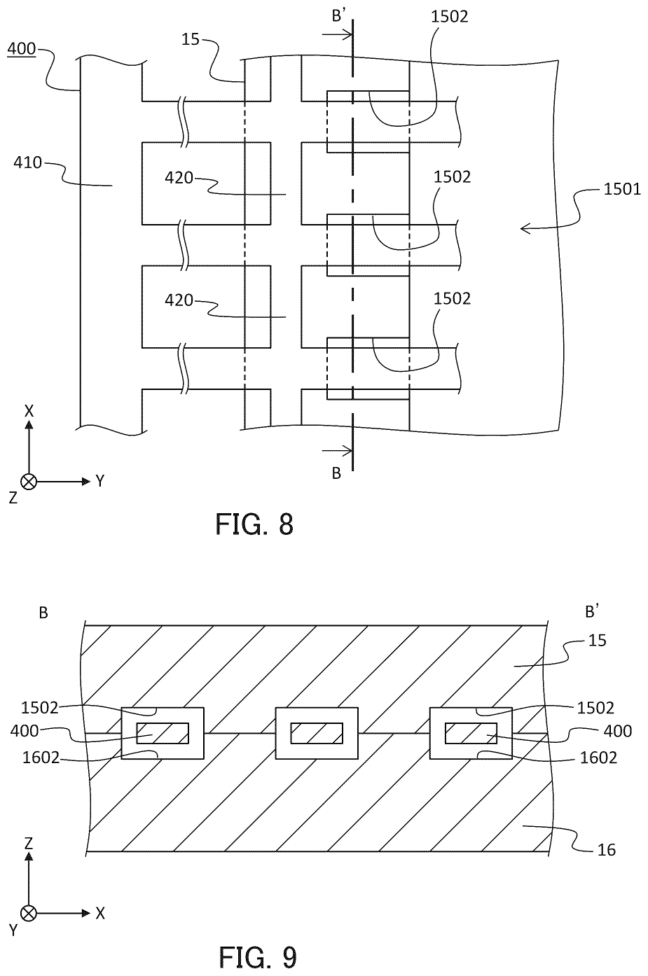

FIG. 6 is a view (part 1) illustrating a method of manufacturing the semiconductor module according to the embodiment. FIG. 7 is a view (part 2) illustrating the method of manufacturing the semiconductor module according to the embodiment. FIG. 8 is a view illustrating a relationship between a lead frame and a cavity of a mold. FIG. 9 is a cross-sectional view taken along an alternate long and short dash line B-B′in FIG. 8. FIGS. 6 and 7 illustrate a mold used to manufacture the semiconductor module 1 in which the entire main body portion 700 illustrated in FIG. 3 is made of the same sealing resin.

The method of manufacturing the semiconductor module 1 according to the present embodiment may be the same as a known method of manufacturing the DIP type semiconductor package, but the sealing member 7 including the main body portion 700 and the covering portion 750 described above is formed in a sealing step of sealing the semiconductor elements 3A, 3B, and the like with an insulating material. Therefore, in the sealing step, for example, transfer molding using molds (an upper mold 15 and a lower mold 16) as illustrated in FIGS. 6 to 9 is performed. The exemplified upper mold 15 and lower mold 16 respectively have a recessed portion 1500 and a recessed portion 1600 formed to have a space (a cavity) 17 corresponding to the outer shape of the sealing member 7 around the semiconductor elements 3A and 3B to be sealed when the upper and lower molds are clamped (refer to FIGS. 6 and 7). Each of the upper mold 15 and the lower mold 16 has a gate (not illustrated) or the like formed therein and adapted to inject an insulating material into the cavity 17 after clamping thereof.

The recessed portion 1500 of the upper mold 15 and the recessed portion 1600 of the lower mold 16 used at the time of manufacturing the semiconductor module according to the present embodiment respectively include first recessed portions 1501 and 1601 adapted to form the main body portion 700 of the sealing member 7 and second recessed portions 1502 and 1602 adapted to form the covering portion 750. For example, as illustrated in FIGS. 8 and 9, the second recessed portions 1502 and 1602 are individually formed for each lead 4 formed in the lead frame 400, and define an annular space from which the surface around the lead 4 is exposed. In the upper mold 15 and the lower mold 16, lead pressing portions 1503 and 1603 are formed at positions facing the outer lead portion of the lead frame 400, in which the lead pressing portions 1503 and 1603 are formed to sandwich the lead frame 400 when the upper and lower molds are clamped and to prevent an insulating material flowing into the second recessed portions 1502 and 1602 from leaking out.

At the time of performing the scaling step, the plurality of leads 4 are in a state of the lead frame 400 integrated by a frame portion 410, a tie bar 411, and the like, and a portion to be the outer lead portion of each lead 4 is not bent. In the plurality of leads 4 in the lead frame 400, adjacent leads 4 are connected to each other by the tic bars 411 or the like at positions not overlapping the cavity 17 defined when the upper mold 15 and the lower mold 16 are clamped.

The shape of the recessed portion 1500 of the upper mold 15 and the recessed portion 1600 of the lower mold 16 is not limited to a specific shape as long as the space (cavity) 17 corresponding to the entire sealing member 7 including the main body portion 700 and the covering portion 750 is defined when the lead frame 400 is sandwiched and clamped. For example, the shape of the recessed portion 1500 of the upper mold 15 and the recessed portion 1600 of the lower mold 16 may be a shape in which a space for forming the case member 710 and the covering portion 750 of the main body portion 700 described above with reference to FIG. 2 is defined when the upper and lower molds are clamped. In addition, the second recessed portions 1502 and 1602 for forming the covering portion 750 may be formed at positions corresponding to the leads 4, the creepage distance of which is desired to be long. That is, the second recessed portions 1502 and 1602 for forming the covering portion 750 may be formed at positions corresponding to one or more leads of all the leads 4 (outer lead portions).

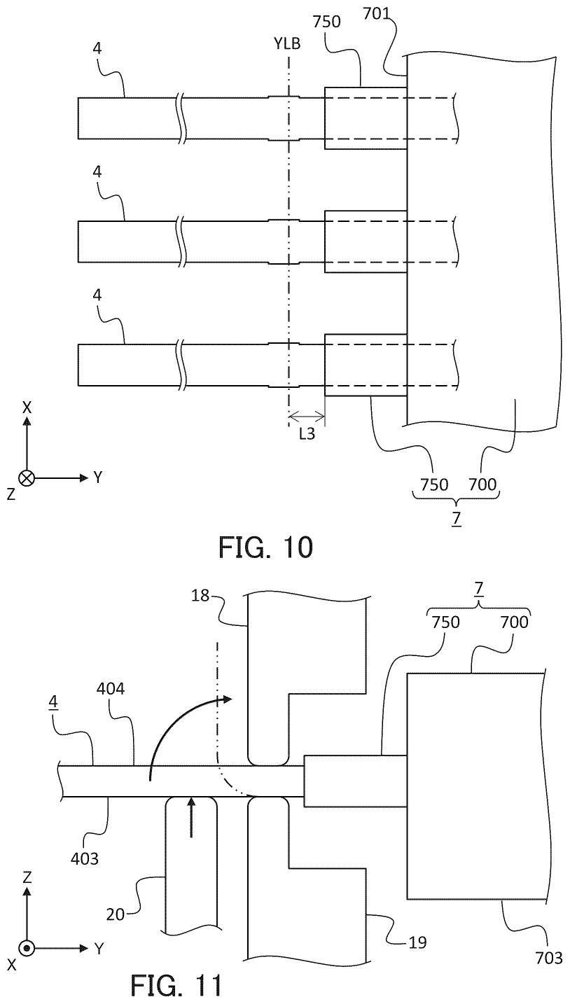

FIG. 10 is a bottom view illustrating an example of a step of dividing a lead into individual leads. FIG. 11 is a front view illustrating an example of a step of bending the outer lead portion. In FIGS. 10 and 11, only the configuration on the end surface 701 side of the main body portion 700 of the sealing member 7 is illustrated, but the configuration on the opposite end surface 702 side may be similar thereto.

After the sealing step, in order to make the plurality of leads in the lead frame 400 (refer to FIG. 8) electrically independent leads, as illustrated in FIG. 10, the frame portion 410 of the lead frame 400 and the tie bar 411 are cut to individualize the leads 4. The frame portion 410 of the lead frame 400 and the tic bar 411 can be cut by, for example, a known method using a mold. After the frame portion 410 of the lead frame 400 and the tie bar 411 are cut, for example, as illustrated in FIG. 11, the outer lead portion is bent at the bending position YLB of the outer lead portion of the lead 4. The bending of the outer lead portion is performed by pressing a mold 20 for molding at a position farther from the covering portion 750 than the bending position YLB in a state in which the lead 4 (outer lead portion) is sandwiched by molds 18 and 19 in the vertical direction at a position at which the surface of the lead 4 is exposed, in which the position is between the bending position YLB and a portion covered with the covering portion 750 of the sealing member 7. At this time, the outer lead portion of the lead 4 is bent so as to extend from the bending position YLB in a direction opposite (the upper surface of the sealing member 7) to the lower surface 703 of the sealing member 7 from which the metal layer 6A of the heat dissipation member 6 is exposed. As described above, by forming a section in which the surface of the lead 4 is exposed between the bending position YLB of the outer lead portion and the portion covered with the covering portion 750 of the scaling member 7, it is possible to prevent, when the outer lead portion is bent, the covering portion 750 of the sealing member 7 from being damaged and peeled, in which the covering portion 750 is damaged and peeled by bending stress applied to the covering portion 750 of the scaling member 7. The bending angle of the outer lead portion is not limited to 90 degrees illustrated in FIGS. 2 and 11. The step of cutting the frame portion 410 of the lead frame 400 and the tie bar 411 and the step of bending the outer lead portion of the lead 4 may be separate steps, or cutting and bending may be performed continuously or simultaneously.

As described above, in the semiconductor module 1 according to the present embodiment, the covering portion 750 covering the outer lead portion of the lead 4 extending from the main body portion 700 is formed to be integrated with the main body portion 700 of the sealing member 7 that seals the semiconductor elements 3A, 3B, and the like. Therefore, the number of manufacturing steps is reduced as compared with a case of coating the outer lead portion after performing scaling with the sealing member and bending the outer lead portion of the lead as described in JP 2020-53611 A, and manufacturing costs of the semiconductor module can be reduced. In addition, by bending the portion at which the surface of the outer lead portion of the lead 4 is exposed (that is, the portion not covered with the covering portion 750) after the covering portion 750 is formed to be integrated with the main body portion 700, for example, a user of the semiconductor module 1 can bend the outer lead portion of the lead 4 at a desired angle after shipment and can adjust the bending angle to a desired angle. Further, the covering portion 750 covers an entire surface of a section of the outer lead portion of the lead 4, in which the section is defined from a boundary between the inner lead portion and the outer lead portion to a position closer to the boundary than the bending position YLB. Therefore, the amount of the resin material used for forming the sealing member 7 can be reduced as compared with a structure in which the entire lead portion is covered with the sealing resin as described in JP 2020-53611 A.

In addition, by integrally forming the covering portion 750 covering the entire surface (upper surface, lower surface, side surface) of the outer lead portion of the lead 4 with the main body portion 700 by transfer molding or the like, a creepage distance between each of the leads 4 and a corresponding one of the adjacent leads 4 and a creepage distance between each lead 4 and the metal layer 6A of the heat dissipation member 6 can be made longer at the covering portion 750. Therefore, as compared with a case of forming a protrusion in contact with a side surface of one of the adjacent leads as described in JP 2013-84838 A, the creepage distance between the lead 4 and the metal layer 6A of the heat dissipation member 6 can be particularly secured. Furthermore, since the surface of the outer lead portion of the lead 4 is covered with the covering portion 750 having a thickness of about 1 mm so as to secure the creepage distance, the amount of the resin material used for forming the sealing member can be reduced as compared with a case of forming a block-shaped protrusion extending from the upper surface to the lower surface of the main body portion as described in JP H06-61375 A.

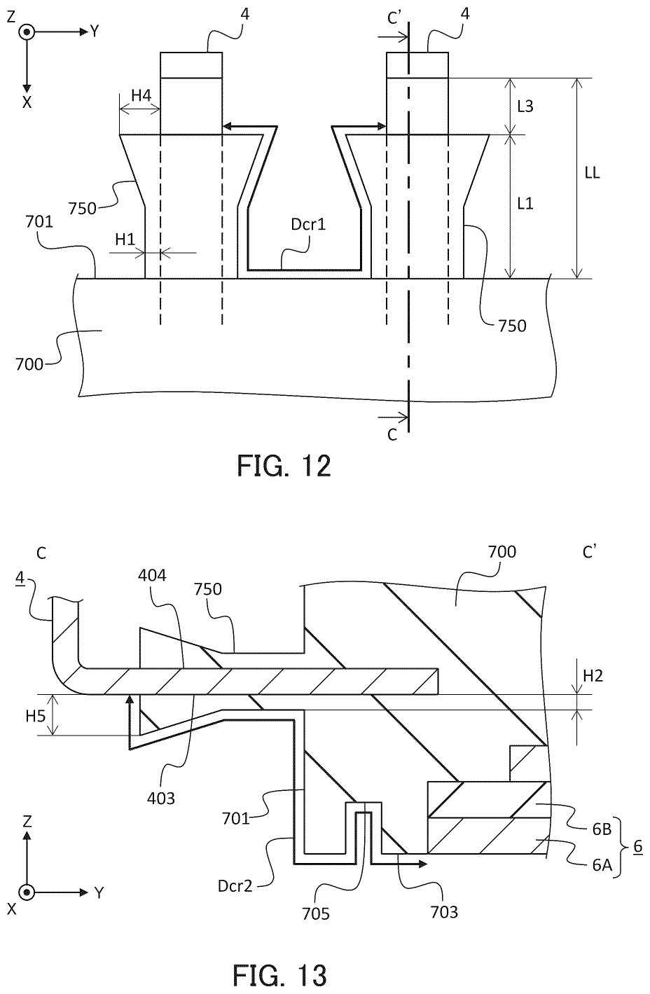

FIG. 12 is a bottom view illustrating a modification of the shape of the covering portion. FIG. 13 is a cross-sectional view taken along an alternate long and short dash line C-C′ in FIG. 12. In FIGS. 12 and 13, only the configuration on the end surface 701 side of the main body portion 700 of the sealing member 7 is illustrated, but the configuration on the opposite end surface 702 side may be similar thereto.

The covering portion 750 of the sealing member 7 in the semiconductor module 1 according to the present embodiment only needs to cover each lead 4 that increases the creepage distance Dcr1 and/or Dcr2 individually, and the shape of the covering portion 750 is not limited to a specific shape. Therefore, as illustrated in FIGS. 12 and 13, for example, the shape of the covering portion 750 may be formed such that a thickness of each surface of the lead 4 as viewed in the extending direction from the main body portion 700 varies, and a distance of a section along the surface of the covering portion 750 in the creepage distances Dcr1 and Dcr2 is longer than the length L1 (that is, the shape having a tapered portion). At the covering portion 750 illustrated in FIGS. 12 and 13, a side close to the main body portion 700 has a thickness H1 and a thickness H2, and a side close to the bending position of the lead 4 has a thickness H4 (>H1) and a thickness H5 (>H2). For example, such the shape of the covering portion 750 makes it possible to secure the longer creepage distances Dcr1 and Dcr2 under the condition that a distance LL from the end surface 701 of the main body portion 700 to the bending position YLB is constant. Under the condition that the creepage distances Dcr1 between the leads 4 and the creepage distance Dcr2 between the lead 4 and the metal layer 6A of the heat dissipation member 6 are constant, the length L1 of the covering portion 750 in the extending direction (Y direction) of the outer lead portion of the lead 4 can be shortened, and the distance LL from the end surface 701 of the main body portion 700 to the bending position YLB can be shortened.

It is noted that the shape of the covering portion 750 is not limited to the shape in which the thickness continuously changes (that is, has a tapered portion) in the extending direction (Y direction) of the lead 4, as illustrated in FIGS. 12 and 13. The shape of the covering portion 750 may be, for example, a shape in which the thickness changes stepwise in the extending direction (Y direction) of the lead 4.

In addition, in the semiconductor module 1 of the present embodiment, as illustrated in FIG. 13, by forming the recessed portion 705 in the lower surface 703 of the main body portion 700 of the sealing member 7, it is possible to more reliably secure the creepage distance Dcr2 between the lead 4 and the metal layer 6A of the heat dissipation member 6. Although not illustrated herein, for example, a recessed portion recessed to the opposite side to the extending direction of the leads 4 may be formed between the adjacent covering portions 750 (between the adjacent leads 4) on the end surface 701 of the main body portion 700, thereby further increasing the creepage distance Dcr1 between the leads 4. The covering portion 750 of the sealing member 7 is formed so as to cover the lead 4 in the lead frame 400, for example, and may be integrated with the main body portion 700 of the sealing member 7 in the sealing step.

The semiconductor module 1 of the above-described embodiment can be applied to, for example, an industrial power conversion device such as an inverter device that drives a motor of an elevator, an escalator, an air conditioning system of a building, or the like. It is noted that the application of the semiconductor module 1 is not limited to a specific application. For example, the semiconductor module 1 can also be applied to a power conversion device such as an inverter device that drives a motor of a vehicle such as a four-wheeled automobile or a railway vehicle. As described above, the circuit formed in the semiconductor module 1 is not limited to the power conversion circuit that converts direct current into alternating current, and may be another circuit.

Hereinafter, feature points in the above-described embodiment will be summarized.

A semiconductor module according to the above-described embodiment includes: a semiconductor element; a sealing member having a main body portion sealing the semiconductor element; and a plurality of leads, each of the leads having an inner lead portion extending to an inside of the main body portion of the sealing member and an outer lead portion extending to an outside of the main body portion, the outer lead portion being bent at a predetermined bending position, in which the sealing member has a covering portion individually covering, for each section of the outer lead portion, an entire surface of the section of the outer lead portion of the lead, in which the section is defined from a boundary between the inner lead portion and the outer lead portion to a position closer to the boundary than the bending position.

In the semiconductor module according to the embodiment, the main body portion of the sealing member is formed to be integrated with the covering portion.

The semiconductor module according to the embodiment further includes an element mounting member configured to allow the semiconductor element to be mounted thereon, in which a surface of the element mounting member, the surface being opposite a surface having the semiconductor element mounted thereon, is exposed from the main body portion of the scaling member.

In the semiconductor module according to the embodiment, the element mounting member includes a die pad having the semiconductor element mounted thereon, and a heat dissipation member disposed on an opposite side of the semiconductor element with the die pad as a boundary therebetween and connected to the die pad, and the heat dissipation member is exposed from the main body portion of the sealing member.

In the semiconductor module according to the embodiment, the main body portion of the sealing member is formed of the same insulating material as an insulating material of the covering portion.

In the semiconductor module according to the embodiment, the main body portion of the sealing member includes: a case member having a space for accommodation of the semiconductor element, the case member being integrated with the lead so as to expose a part of the inner lead portion of the lead in the space; and an insulating member filling the space of the case member.

In the semiconductor module according to the embodiment, the covering portion of the sealing member is formed to be integrated with the case member.

The semiconductor module according to the embodiment further includes an element mounting member configured to allow the semiconductor element to be mounted thereon, in which the case member and the element mounting member are bonded to each other by the insulating member filling the space of the case member so as to expose, from the main body portion, a surface of the element mounting member, the surface being opposite a surface having the semiconductor element mounted thereon.

The semiconductor module of the embodiment further includes a cooler connected to the element mounting member, in which the outer lead portion of the lead is formed to extend outwards from an end surface located at an end in a direction parallel to an in-plane direction of a surface of the main body portion of the sealing member, the surface having the element mounting member exposed therefrom, and to have a portion formed from the bending position to an end portion opposite the boundary between the inner lead portion and the outer lead portion, the portion being bent in a direction away from the cooler.

In the semiconductor module according to the embodiment, a thickness of the covering portion on a side close to the bending position is larger than a thickness of the covering portion on a side close to the boundary between the inner lead portion and the outer lead portion.

In the semiconductor module according to the embodiment, a recessed portion is formed in a surface of the main body portion of the sealing member, the surface having the element mounting member exposed therefrom.

In the semiconductor module according to the embodiment, the main body portion of the sealing member has a power conversion circuit formed therein, the power conversion circuit including the semiconductor element.

It is noted that the present invention is not limited to the above-described embodiments, and various changes, substitutions, and modifications may be made without departing from the spirit of the technical idea. Further, when the technical idea can be realized in another manner by the progress of the technology or another derived technology, the technical idea may be carried out by using a method thereof. Therefore, the claims cover all implementations that may be included within the scope of the technical idea.

### Industrial Applicability

As described above, the present invention can suppress an increase in manufacturing costs of a semiconductor module due to an increase in a creepage distance related to insulation performance, an increase in size of the semiconductor module, and the like, and is particularly advantageous for application to a power conversion device (an inverter device) having a high breakdown voltage.

What is claimed is:

1. A semiconductor module, comprising:
a semiconductor element;
a sealing member having a main body portion that seals the semiconductor element; and
a plurality of leads, each of the leads having an inner lead portion extending to an inside of the main body portion of the sealing member and an outer lead portion extending to an outside of the main body portion, the outer lead portion being bent at a predetermined bending position, the semiconductor element being electrically connected to one of the plurality of leads, wherein
the sealing member has a covering portion individually covering an entire surface of a section of the outer lead portion of each lead, the section of the outer lead portion being defined from a boundary between the inner lead portion and the outer lead portion to a position of the outer lead that is closer to the boundary than is the bending position.

2. The semiconductor module according to claim 1, wherein the main body portion of the sealing member is integrated with the covering portion.

3. The semiconductor module according to claim 1, further comprising an element mounting member configured to allow the semiconductor element to be mounted on a mounting surface thereof, wherein
a surface of the element mounting member opposite to the mounting surface of the element mounting member is exposed to the outside from the main body portion.

4. The semiconductor module according to claim 3, wherein:
the element mounting member includes a die pad having the semiconductor element mounted thereon, and a heat dissipation member disposed on a side of the die pad opposite to a side of the die pad where the semiconductor element is mounted and is connected to the die pad, and
the heat dissipation member is exposed from the main body portion.

5. The semiconductor module according to claim 1, wherein the main body portion of the sealing member and the covering portion are formed of the same insulating material.

6. The semiconductor module according to claim 1, wherein
the main body portion of the sealing member includes:
a case member having a space for accommodating the semiconductor element, the case member being integrated with the lead so that a part of the inner lead portion of the lead is disposed within the space; and
an insulating member filling the space to seal the part of the inner lead portion.

7. The semiconductor module according to claim 6, wherein the covering portion of the sealing member is integrated with the case member.

8. The semiconductor module according to claim 6, further comprising an element mounting member configured to allow the semiconductor element to be mounted on a mounting surface thereof, wherein
the case member and the element mounting member are bonded to each other by the insulating member that fills the space of the case member such that a surface of the element mounting member that is opposite to the mounting surface of the element mounting member is exposed to the outside of the main body portion.

9. The semiconductor module according to claim 3, further comprising a cooler connected to the element mounting member, wherein
the outer lead portion of the lead is formed to:
extend outwards from an end surface of the main body portion located at an end of the main body portion in a direction parallel to a surface of the main body portion from which the element mounting member is exposed; and
have a portion, which is from the bending position to one end of the outer lead portion that is opposite to another end of the outer lead portion located at the boundary between the inner lead portion and the outer lead portion, that is bent in a direction away from the cooler.

10. The semiconductor module according to claim 1, wherein a thickness of the covering portion at one side thereof that is closer to the bending position than is another side thereof is larger than a thickness of the another side thereof, the another side of the covering portion being closer to the boundary between the inner lead portion and the outer lead portion than is the one side of the covering portion.

11. The semiconductor module according to claim 3, wherein the main body portion of the sealing member has a recess that is recessed inside the main body portion from a surface thereof, from which the element mounting member is exposed.

12. The semiconductor module according to claim 1, wherein the semiconductor element in the main body portion of the sealing member forms a power conversion circuit.
